(19) United States
(12) Patent Application Publication
(10) Pub. No.: US 2019/0207135 A1
(43) Pub. Date: Jul. 4, 2019

(54) DISPLAY PANEL AND DISPLAY DEVICE

(71) Applicant: BOE TECHNOLOGY GROUP CO., LTD., Beijing (CN)

(72) Inventor: Boris KRISTAL, Beijing (CN)

(21) Appl. No.: 16/119,518

(22) Filed: Aug. 31, 2018

(30) Foreign Application Priority Data
Jan. 3, 2018 (CN) 201810005500.2

(51) Int. Cl. H01L 51/42; G02F 1/133; H01L 51/44; H01L 27/28; H01L 31/032

(52) U.S. Cl. CPC H01L 51/4213; G02F 1/13306; H01L 51/442; G02F 1/1337; H01L 31/0321; G02F 2001/13324; H01L 27/288

(57) ABSTRACT

The embodiments of the present disclosure provides a display panel and a display device. The display panel includes a display layer, and a solar cell disposed on the side of light emitting of the display layer and located on at least the part of display region of the display layer; the solar cell is used to supply power for the display layer; the solar cell comprises a first electrode and a second electrode which are transparent, and a photoelectric conversion layer disposed between the first electrode and the second electrode, the photoelectric conversion layer is configured to transmit at least a part of visible light, and to convert the absorbed light into electrical energy.

### CROSS-REFERENCE TO RELATED APPLICATION

This application claims priority to Chinese Patent Application No. 201810005500.2, filed on Jan. 3, 2018, titled “DISPLAY PANEL AND DISPLAY DEVICE”, which is incorporated herein by reference in its entirety.

### TECHNICAL FIELD

The present disclosure relates to a display technology field, in particular, to a display panel and display device.

### BACKGROUND

With the improvement of technology, various types of display devices have gradually developed, such as liquid crystal display device, organic electro-luminescent display device and quantum dot electro-luminescent display device and so on; these display devices are generally applied to mobile devices such as mobile phones, tablet phones and tablet computers. Existing mobile devices consume a large amount of power due to the large number of application programs, and large size.

### SUMMARY

The embodiments of the present disclosure adopt the following technical solutions:

A display panel, wherein, the display panel comprises a display layer, and a solar cell disposed on the side of light emitting of the display layer and located on at least a part of display region of the display layer; the solar cell is used to supply power for the display layer;

The solar cell comprises a first electrode and a second electrode which are transparent, and a photoelectric conversion layer disposed between the first electrode and the second electrode, the photoelectric conversion layer is configured to transmit at least a part of visible light, and to convert the absorbed light into electrical energy.

In some embodiments, the photoelectric conversion layer is configured to transmit visible light, and to absorb invisible light and to convert the absorbed invisible light into electrical energy.

In some embodiments, the invisible light is ultraviolet light.

In some embodiments, the photoelectric conversion layer comprises a first semiconductor layer and a second semiconductor layer; the first semiconductor layer contacts the second semiconductor layer for forming a heterojunction.

In some embodiments, the first semiconductor layer and the second semiconductor layer are stacked.

In some embodiments, the material of the first semiconductor is N-type semiconductor material, the material of the second semiconductor is P-type semiconductor material; the work function of the first electrode is lower than the work function of the second electrode; wherein, the first semiconductor layer is closer to the first electrode than the second semiconductor layer.

In some embodiments, the material of the first semiconductor layer is selected from at least one of niobium-doped strontium titanate or niobium-doped titanium oxide.

In some embodiments, the concentration of the niobium-doped strontium titanate or niobium-doped titanium oxide is 0.007˜0.013 wt %, in terms of element niobium.

In some embodiments, the material of the second semiconductor is selected from at least one of Poly(3,4-ethylenedioxythiophene):poly(styrenesulfonate), Poly[2-methoxy-5-(2-ethylhexyloxy)-1,4-phenylenevinylene], or Poly[[5-(2-ethylhexyl)-5,6-dihydro-4,6-dioxo-4H-thieno[3,4-c]pyrrole-1,3-diyl](4,4′-didodecyl[2,2′-bithiophene-5,5′-diyl)].

In some embodiments, the thickness of the first semiconductor layer is 0.5 μm−1 mm.

In some embodiments, the thickness of the first semiconductor layer is 50 μm−500 μm.

In some embodiments, the thickness of the second semiconductor layer is 0.1 μm−5 μm.

In some embodiments, the thickness of the second semiconductor layer is 0.3 μm−1 μm.

In some embodiments, the first electrode, the first semiconductor layer, the second semiconductor layer and the second electrode are sequentially disposed along the light emitting direction of the display layer.

In some embodiments, the second electrode, the second semiconductor layer, the first semiconductor layer and the first electrode are sequentially disposed along the light emitting direction of the display layer.

In some embodiments, the solar cell is disposed such that in a case where the display layer comprises a plurality of top-emitting light display units, the solar cell is disposed on the top of the display layer; or, in a case where the display layer comprises a plurality of bottom-emitting light display units, the solar cell is disposed on the bottom of the display layer.

In another aspect, the embodiments of the present disclosure provide a display device, which comprises the display panel described above.

In some embodiments, the display device further comprises a detection circuit and a processor; the detection circuit is connected with the first electrode and the second electrode respectively, for detecting the magnitude of the photocurrent output from the first electrode and the second electrode; the processor is connected with the detection circuit, for adjusting the display brightness of the display layer according to the magnitude of the photocurrent detected by the detection circuit; and/or for obtaining the irradiance of the invisible light according to the magnitude of the photocurrent detected by the detection circuit, and outputting the value of the irradiance of the invisible light.

In some embodiments, the first electrode and the second electrode of the solar cell are electric energy outputting electrodes which are connected with the power supply circuit of the display device or with a storage battery.

### BRIEF DESCRIPTION OF THE DRAWINGS

In order to illustrate the technical solution in the embodiments of the present disclosure or the related art more clearly, the drawings required to be used in the embodiments or the related art will be simply described as below. Obviously, the drawings in the following description is merely some embodiments of the present disclosure, other drawings may be obtained according to these drawings without paying any creative work for a skilled person in the art.

FIG. 1 is the schematic diagram of the structure of the display panel provided by an embodiment of the present disclosure;

FIG. 2 is the schematic diagram of the structure of the display panel provided by another embodiment of the present disclosure;

FIG. 3 is a absorption spectrogram of niobium-doped strontium titanate thin film;

FIG. 4 is the schematic diagram of the relationship between the photovoltaic response characteristic curve and wavelength of niobium-doped strontium titanate/Poly(3,4-ethylenedioxythiophene):poly(styrenesulfonate) heterojunction solar cell;

FIG. 5 is the schematic diagram of the structure of the display unit provided by an embodiment of the present disclosure;

FIG. 6 is the schematic diagram of the structure of the display panel provided by another embodiment of the present disclosure;

FIG. 7 is the schematic diagram of the structure of the display panel provided by a further embodiment of the present disclosure;

FIG. 8 is the schematic diagram of the structure of the display device provided by an embodiment of the present disclosure;

FIG. 9 is the schematic diagram of the structure for adjusting the display brightness of a mobile phone, which is provided by an embodiment of the present disclosure.

### DETAILED DESCRIPTION

The technical solutions in the embodiments of the present disclosure will be described clearly and completely with reference to the accompanying drawings in the embodiments of the present disclosure. Obviously, the described embodiments are merely some but not all of embodiments of the present disclosure. All other embodiments made on the basis of the embodiments of the present disclosure by a skilled person in the art without paying any creative effort shall be included in the protection scope of the present disclosure.

At present, methods for improving battery life are normally adding some components which may generate electricity into mobile devices, such as disposing a solar cell somewhere on the surface of a mobile device. Since the existing solar cell absorbs visible light, in order to avoid the influence of the solar cell on the light emitted from the display device, the solar cell is generally disposed on the frame around the side of light emitting of the display device or on the back surface of the display device. However, since the existing display devices are all of a narrow frame or frameless design, it is impossible to provide a solar cell on the frame around the display device; if the solar cell is disposed on the back surface of the display device, since the side of light emitting of the display device is generally facing up during use of the users, this will cause the solar cells cannot effectively charge the display device.

Embodiments of the present disclosure provides a display panel, as shown in FIG. 1, comprising a display layer 01, and a solar cell 02 disposed on the side of light emitting of the display layer 01 and located on at least a part of display region of the display layer, the solar cell 02 is used to supply power for the display layer 01; the solar cell 02 comprises a first electrode 10 and a second electrode 20 which are transparent, and a photoelectric conversion layer 30 disposed between the first electrode 10 and the second electrode 20, the photoelectric conversion layer 30 is used to transmit at least a part of visible light, and to convert the absorbed light into electrical energy.

In some embodiments, the photoelectric conversion layer 30 is used to transmit visible light, to absorb invisible light, and to convert the absorbed invisible light into electrical energy.

It should be illustrated that, firstly, the type of the display panel provided by the embodiments of the present disclosure will not be limited, it can be a liquid crystal display panel (LCD); or an organic electro-luminescent display panel (OLED); and certainly it may also be a quantum dot electro-luminescent display panel (QLED) or other types of display panel.

The structure of the display layer 01 will not be limited, which is specifically related to the type of the display panel. When the display panel is a liquid crystal display panel, the display layer 01 comprises an array substrate, an alignment substrate and a liquid crystal layer disposed between the array substrate and the alignment substrate; when the display panel is an organic or quantum dot electro-luminescent display panel, the display layer 01 comprises a plurality of pixels, through which the images are displayed, each pixel comprises an anode, a cathode and a light-emitting functional layer disposed between the anode and the cathode; the anode and the cathode provide holes and electrons for the light-emitting functional layer, for forming one exciton, when the exciton returns to a stable ground state from the excited state in a way of radiation transition, a predetermined wavelength of light is formed, lights having wavelengths corresponding to red, green, and blue colors may be formed according to the material characteristics of the light-emitting functional layer. Herein, when the display panel is an organic electro-luminescent display panel, the light-emitting functional layer is an organic light-emitting functional layer; when the display panel is a quantum dot electro-luminescent display panel, the light-emitting functional layer is a quantum dot light-emitting functional layer.

Secondly, the structure and the material of the photoelectric conversion layer 30 will not be limited, as long as the photoelectric conversion layer 30 can transmit a part of visible light, and convert the absorbed light into electric energy. The degree of transmitting the part of visible light is not limited as long as it does not affect the display function of the display layer 01.

Thirdly, the first electrode 10 and the second electrode 20 may be the anode and the cathode of the solar cell 02, or be the cathode and the anode of the solar cell 02.

Fourthly, the electric energy converted by the solar cell is used to supply power to display layer 01, the electric energy converted by the solar cell 02 may first be stored in a storage battery, and then the storage battery supplies power to the display layer 01; or the electric energy converted by the solar cell 02 may directly input into the circuit which supply power to the display layer 01.

Fifthly, the solar cell 02 is located in the display region of the display layer 01, the solar cell 02 may be located in the part of the display region of the display layer 01, and also may be located in the whole display region of the display layer 01.

In some embodiments, the solar cell 02 covers a part of the display region of the display layer 01; in some other embodiments, the solar cell 02 covers the whole display region of the display layer 01.

Sixthly, since the solar cell 02 in the display panel provided by the embodiments of the present disclosure transmits a part of visible light, and absorbs the rest part of the visible light, the normal display of the display layer 01 will not be interfered.

In some embodiments, solar cell 02 transmits visible light, and only absorbs invisible light. For example, the absorbed invisible light comprises such as infrared light or ultraviolet light, etc.

In some embodiments, the solar cell 02 absorbs ultraviolet light, which further absorbs ultraviolet light in UV-B wave band (ultraviolet light with a wavelength of 290-320 nm).

Since the radiation energy of the ultraviolet light is high, the solar cell of the embodiments of the present disclosure has a higher photoelectric conversion efficiency than the solar cell absorbing visible light; generally, it can reach approximately 16%.

Embodiments of the present disclosure provides a display panel, the display panel comprises a display layer 01 and a solar cell 02 disposed on the side of light emitting of the display layer 01, since the solar cell is used to transmit a part of visible light, to absorb invisible light and absorb optionally the rest part of visible light, and to convert the absorbed light into electric energy, while the light emitted by the display layer 01 is visible light, the solar cell 02 may be disposed on the display region of the display layer 01, without affecting the light emitted by the display layer 01, as thus, the problem that the solar cell 02 can only be disposed at the position of the frame of the display panel in the related art is solved. On this basis, relative to disposing the solar cell 02 in the related art on the back surface of the display panel, since the solar cell 02 is disposed on the side of light emitting of the display layer 01 in the embodiments of the present disclosure, invisible light may be absorbed sufficiently, and the display layer 01 will be charged effectively.

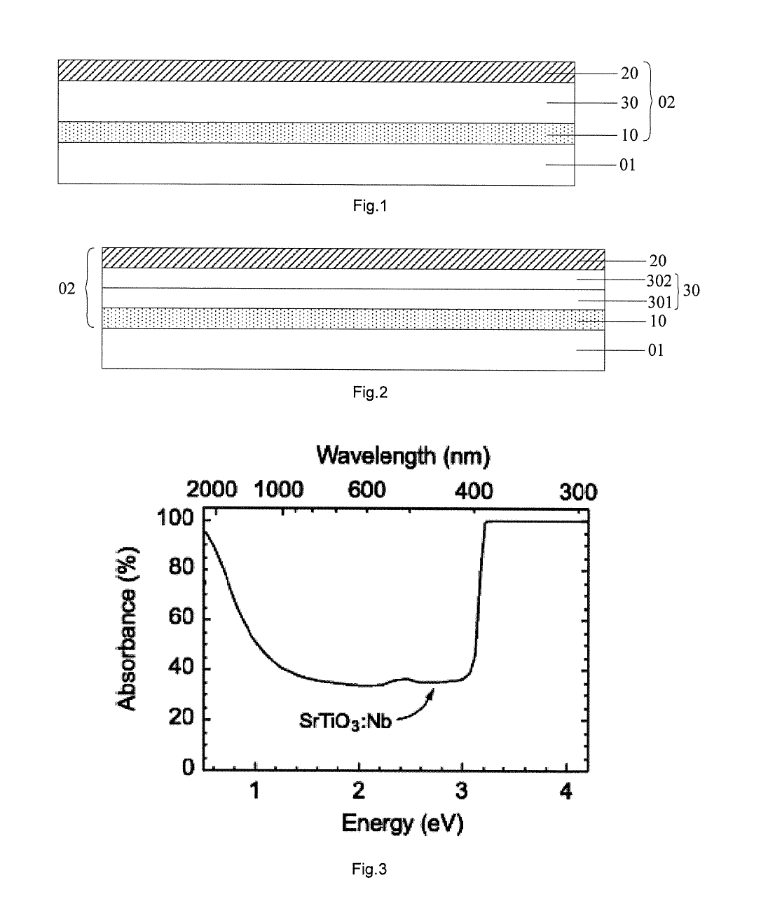

In some embodiments, as shown in FIG. 2, the photoelectric conversion layer 30 comprises a first semiconductor layer (also called active media layer) 301 and a second semiconductor layer 302; the first semiconductor layer 301 contacts the second semiconductor layer 302 for forming a heterojunction.

In some embodiments, the first semiconductor layer 301 and the second semiconductor layer 302 are stacked.

In some embodiments, the heterojunction refers to an interface region formed by the contact of two different semiconductors, PN junction is a kind of heterojunction.

The working principle of the solar cell is: as the sunlight irradiate the PN junction, electrons in the semiconductor is released due to obtaining luminous energy, and accordingly electron-hole pairs are generated, and under the action of barrier electric field, the electrons are driven toward the N-type region, and holes are driven toward the P-type region, thereby N-type region has excess electrons, and the P-type region has excess holes; in this way, a photogenerated electric field opposite to the barrier electric field is formed near the PN junction. A part of the photogenerated electric field offsets the barrier electric field, and the rest part comprises the P-type region positive charged, and N-type region negatively charged, so that the thin layer between the P-type region and the N-type region generates electromotive force, when the external circuit is turned on, there is electric energy output.

Herein, the materials of the first semiconductor layer 301 and the second semiconductor layer 302 will not be limited, as long as the contact between the first semiconductor layer 301 and the second semiconductor layer 302 is able to form the heterojunction.

Embodiments of the present disclosure, since the heterojunction is formed between the receptor and the donor, and the heterojunction contributes to separate electrons, the contact of the first semiconductor layer 301 and the second semiconductor layer 302 forms the heterojunction, which may improve the photoelectric conversion efficiency of the solar cell 02.

Further in some embodiments, the material of the first semiconductor layer 301 is N-type semiconductor material, the material of the second semiconductor layer 302 is P-type semiconductor material; the work function of the first electrode 10 is lower than the work function of the second electrode 20; in some embodiments, the first semiconductor layer 301 is closer to the first electrode than the second semiconductor layer 302.

In some embodiments, the material of the first electrode 10 will not be limited, to have a lower work function as the criterion. Illustratively, it may be transparent conductive oxide such as indium zinc oxide (IZO) or aluminum doped zinc oxid (AZO); or may be a metal net formed by using metal such as silver (Ag), aluminum (Al), etc. or other transparent material with lower work function.

The material of the second electrode 20 will not be limited, to have a higher work function as the criterion. Illustratively, it may be indium tin oxide (ITO), silver paste, gold paste, patterning metal thin film layer, metal nanowire, etc. Herein, it should be illustrated that the silver paste and the gold paste are a kind of metal organic complexes, as their thickness is smaller than 200 nm, the thin film formed by the silver paste or gold paste is transparent at this moment.

It should be illustrated that, the forming process of the first semiconductor layer 301 will not be limited, for example it may adopt magnetron sputtering deposition, atomic layer deposition or other method for deposition. In some embodiments, the thickness of the first semiconductor layer 301 is 0.5 μm−1 mm, further in some embodiments, the thickness o the first semiconductor layer is 50 μm−500 μm. The forming process of the second semiconductor layer 302 will not be limited, for example it can adopt spin-coating method, slit-coating method or deposition method. In some embodiment, the thickness of the second semiconductor layer 302 is 0.1 μm−5 μm; further in some embodiments, the thickness of the second semiconductor layer 302 is 0.3 μm−1 μm.

Herein, the first electrode 10, the first semiconductor layer 301, the second semiconductor layer 302 and the second electrode 20 may be sequentially disposed along the light emitting direction of the display layer 01; the second electrode 20, the second semiconductor layer 302, the first semiconductor layer 301, and the first electrode 10 may also be sequentially disposed.

Embodiments of the present disclosure, the work function of the first electrode 10 is lower than the work function of the second electrode 20, the material of the first semiconductor layer 301 is N-type semiconductor material, and when the first semiconductor layer 301 is close to the first electrode 10, the photoelectric conversion efficiency of the solar cell 02 may be improved.

Based on the above description, in some embodiments, the material of the first semiconductor layer 301 is selected from at least one of the niobium-doped strontium titanate (SrTiO₃:Nb) or niobium-doped titanium oxide (TiO₂:Nb).

Herein, when the material of the first semiconductor layer 301 is niobium-doped strontium titanate or niobium-doped titanium oxide, the concentration of the niobium-doped strontium titanate or niobium-doped titanium oxide may be approximately 0.01 wt %, such as 0.007˜0.013 wt %, in terms of element niobium.

In some embodiments, strontium titanate (SrTiO₃) and titanic oxide (such as titanium oxide) are very stable compounds, the band gap of strontium titanate and titanium oxide are 3.2 eV and 3.0 eV respectively, which can absorb light with wavelengths below 390 nm and 410 nm respectively, they are insensitive to visible light, and are unable to absorb visible light. Since strontium titanate belongs to an almost direct band gap semiconductor, with large absorption coefficient, which is approximately 105 cm⁻¹; at room temperature, carrier density of strontium titanate doped with 0.01 wt % of niobium is approximately 5.2×10¹⁷ cm⁻³, and the Hall mobility is approximately 4.9 cm²/V·s, which is considerably high in semiconductor materials, and having a favorable semiconductor performance. The property of titanium oxide is similar to that of strontium titanate, and will not be described here.

Illustratively, FIG. 3 is the absorption spectrogram of 0.5 mm niobium-doped strontium titanate thin film, it can be seen from FIG. 3 that SrTiO₃:Nb has a strong absorption capacity in the ultraviolet light range (less than 400 nm), but the absorption in the visible range is very low.

Embodiments of the present disclosure, when the material of the first semiconductor layer 301 is selected from at least one of the niobium-doped strontium titanate or niobium-doped titanium oxide, the path for transmitting light in the first semiconductor layer 301 (i.e. active dielectric layer) may be increased, the absorption of light by the solar cell 02 is promoted, and the photocurrent and efficiency of the solar cell 02 are improved.

In some embodiments, the material of the second semiconductor layer 302 is selected from at least one of PEDOT:PSS (Poly(3,4-ethylenedioxythiophene):poly(styrenesulfonate)), MEH-PPV (Poly[2-methoxy-5-(2-ethylhexyloxy)-1,4-phenylenevinylene]), or PBTTPD (Poly[[5-(2-ethylhexyl)-5,6-dihydro-4,6-dioxo-4H-thieno[3,4-c]pyrrole-1,3-diyl](4,4′-di dodecyl[2,2′-bithiophene-5,5′-diyl)]).

Embodiments of the present disclosure, when the material of the second semiconductor layer 302 is selected from at least one of PEDOT:PSS, MEH-PPV, or PBTTPD, the conversion efficiency of the solar cell can be improved.

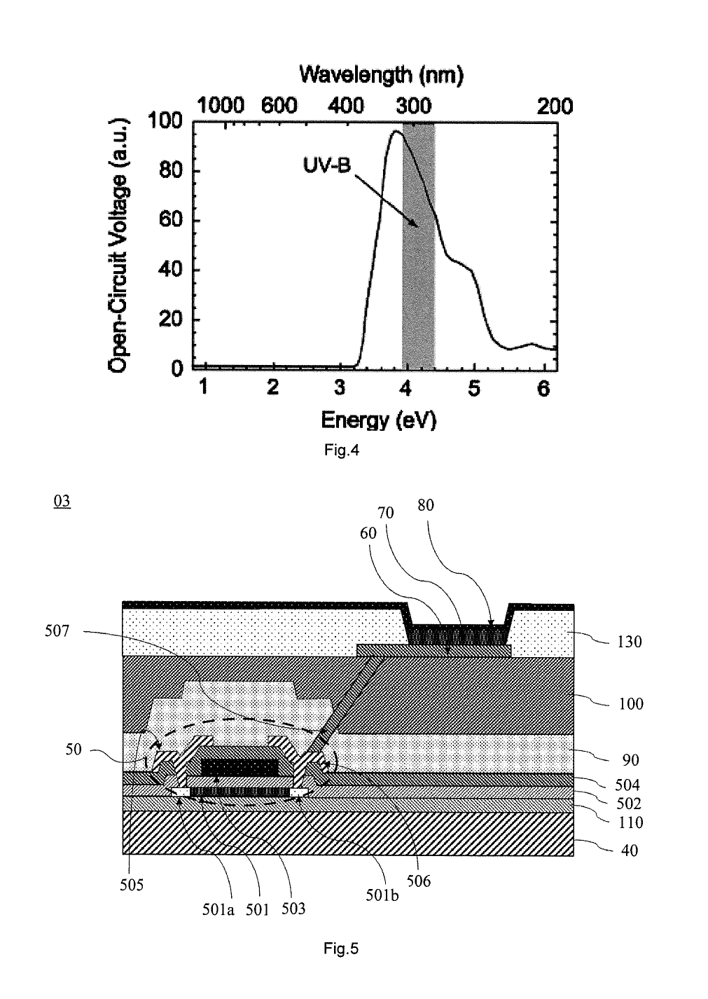

Illustratively, when the material of the first semiconductor layer 301 is SrTiO₃:Nb, and the material of the second semiconductor layer 302 is PEDOT:PSS, the relationship between the photovoltaic response characteristic curve and wavelength of the SrTiO₃:Nb/PEDOT:PSS heterojunction solar cell is shown in FIG. 4, the gray area in FIG. 4 corresponds to the wavelength range of the UV-B band. It can be seen from FIG. 4, SrTiO₃:Nb/PEDOT:PSS heterojunction solar cell has a strong absorption to the ultraviolet light in UV-B band, with a large open-circuit voltage.

Since organic electro-luminescent display panel and quantum dot electro-luminescent display panel have the advantages of low voltage driven, high luminous efficiency, high contrast, flexibility, wide viewing angle, etc., in some embodiments of the embodiments of the present disclosure, the display panel is an organic electro-luminescent display panel or a quantum dot electro-luminescent display panel.

When the display panel is the organic electro-luminescent display panel or the quantum dot electro-luminescent display panel, the display layer 01 comprises a plurality of display units 03. The structure of the display unit 03 will not be limited. Illustratively, as shown in FIG. 5 the display unit 03 may comprise: a thin film transistor 50 disposed on a base substrate 40, an anode (also called pixel electrode) 60, a light-emitting functional layer (also called interlayer) 70 and a cathode (also called counter electrode or common electrode) 80, the thin film transistor 50 comprises an active layer 501, a gate insulating layer 502, gate electrode 503, an interlayer insulating layer 504, a source electrode 505 and a drain electrode 506 disposed on the base substrate 40 sequentially, the source electrode 505 is in contact with a source electrode contact region 501a of the active layer 501 through a via hole, the drain electrode 506 is in contact with a drain electrode contact region 501b of the active layer 501 through a via hole; the drain electrode 506 of the thin film transistor 50 is electrically connected with the anode 60 through a connection portion 507, gate electrode 503 is electrically connected with the gate line (not illustrated in FIG. 5), for applying an turn on/off signal to the thin film transistor 50. Herein, the material of the base substrate 40 will not be limited, for example it may be glass or plastic.

Based on the above description, display layer 01 emits red light, green light or blue light through a plurality of display units 03 to display one predetermined image. The anode 60 is electrically connected with the drain electrode 506 of the thin film transistor 50, and receives positive voltage from drain electrode 506; cathode 80 provides negative voltage to the light-emitting functional layer 70. The brightness of the red light, green light, or blue light emitted from the light-emitting functional layer 70 depends on the magnitude of the current. The light-emitting functional layer 70 and the anode 60 of each display units 03 are spaced apart from each other through a pixel definition layer 130.

In addition, the display unit 03 further comprises a passivation layer 90 and a planarization layer 100 which are sequentially disposed on the thin film transistor 50, and the anode 60 is disposed on the planarization layer 100. The material of the passivation layer 90 will not be limited, for example it may be at least one of silicon nitride (SiNₓ), silicon oxide (SiOₓ), or silicon oxynitride (SiOₓN_{y}). The material of the planarization layer 100 will not be limited. In some embodiments, the material of the planarization layer 100 may be organic material. In some embodiments, the material of the planarization layer 100 may be at least one of acrylic plastic, which is commonly known as acryl, polyimide or benzocyclobutene (BCB).

On this basis, the display unit 03 may further comprise a buffer layer 110 disposed between the base substrate 40 and thin film transistor 50.

When the display panel provided by the embodiments of the present disclosure is the organic electro-luminescent display panel or the quantum dot electro-luminescent display panel, the display unit 03 of the display layer 01 may be a top-emitting light unit, or a bottom-emitting light unit, which will not be limited.

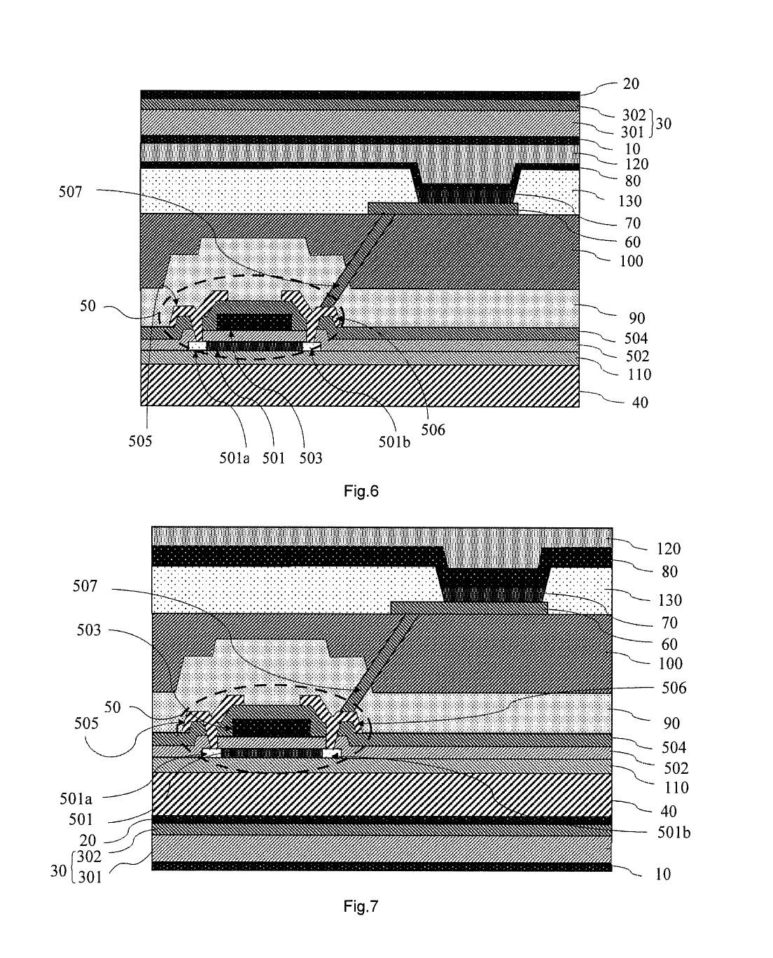

In the case where the display layer 01 comprises a plurality of top-emitting light display unit 03, that is the light emitted from the display unit 03 is emitted from the cathode 80, as shown in FIG. 6, the solar cell 02 is disposed on the top of the display layer 01.

When the solar cell 02 is disposed on the top of the display layer 01, an encapsulation layer 120 may first be disposed on the display layer 01, and then the solar cell 02 is disposed on the encapsulation layer 120.

Optionally, in the case where the display layer 01 comprises a plurality of bottom-emitting light display unit 03, that is the light emitted from the display unit is emitted from the anode 60, as shown in FIG. 7, the solar cell 02 is disposed on the bottom of the display layer 01.

When the solar cell 02 is disposed on the bottom of the display layer 01, the solar cell 02 may be disposed on one side of the base substrate 01 away from the display layer 01; or the solar cell 02 and the display layer 01 may be disposed on the same side of the base substrate 40; the solar cell 02 may first be formed on the base substrate 40 at this moment, and then the display layer 01 may be formed on the solar cell 02, the display layer 01 may be encapsulated by the encapsulation layer 120.

The embodiments of the present disclosure provides a display device, comprises the display panel described above.

The display device provided by the embodiments of the present disclosure may be any product or components of mobile phones, tablet phones, tablet computers, notebook computers, digital camera, navigator, etc. having display function.

The embodiments of the present disclosure provides a display device, the display panel of the display device comprises a display layer 01 and a solar cell 02 disposed on the side of light emitting of the display layer 01, since the solar cell 02 is used to transmit at least a part of visible light, and to convert the absorbed light into electric energy, while the light emitted from the display layer 01 is visible light, the solar cell 02 may be disposed on the display region of the display layer 01, without affecting light emitted from the display layer 01; as thus, the problem that the solar cell 02 may only be disposed at the position of the frame of the display panel in the related art is solved. On this basis, relative to disposing the solar cell 02 on the back surface of the display panel in related art, since the solar cell 02 is disposed on the side of light emitting of the display layer 01 in the embodiments of the present disclosure, invisible light such as ultraviolet light may be sufficiently absorbed, and the display layer may be effectively charged.

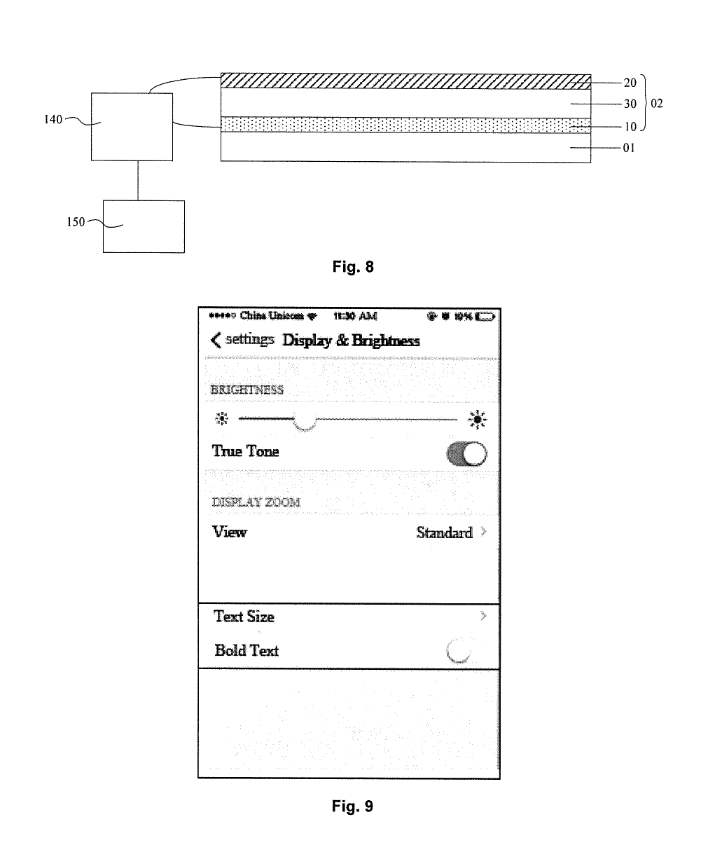

In some embodiments, as shown in FIG. 8, the display device further comprises a detection circuit 140 and a processor 150; the detection circuit 140 is connected with the first electrode 10 and the second electrode 20 respectively, for detecting the magnitude of the photocurrent output from the first electrode 10 and the second electrode 20; the processor 150 is connected with the detection circuit 140, for adjusting the display brightness of the display layer 01, according to the magnitude of the photocurrent detected by the detection circuit 140; and/or for obtaining the irradiance of the invisible light according to the magnitude of the photocurrent detected by the detection circuit 140, and outputting the value of the irradiance of the invisible light. In some embodiments, the invisible light is ultraviolet light.

Herein, since the solar cell 02 provided by the embodiment of the disclosure can only absorb the invisible light such as ultraviolet light, and convert the absorbed light into the electric energy, and there are generally few elements of invisible light such as ultraviolet light in artificial light source, the magnitude of the photocurrent generated by the solar cell 02 which is detected by the detection circuit 140 is related to the magnitude of the electric energy converted by the solar cell 02. The greater the photocurrent detected by the detection circuit 140 is, the greater the electric energy converted by the solar cell 02 is, and the more the ultraviolet light the solar cell 02 absorbs, and then it can be known that the intensity of the ambient light are higher. On this basis, according to the magnitude of the photocurrent detected by the detecting circuit 140, it can be obtained whether the display device is currently used indoors, or is used outdoors and the intensity of ambient light when used outdoors.

For reducing the power consumption of the display device, the brightness of the display device is generally changed according to the ambient light intensity; in detail, the display brightness of the display device is reduced indoors, and the display brightness of the display device is increased in the case where the sunlight irradiates outdoors. In related art, an ambient light sensor (such as a photosensitive diode sensor) is generally disposed in the display device, adjusting the display brightness of the display device according to the ambient light intensity detected by the ambient light sensor. Since the display device is whether used indoors or used outdoors at present and the ambient light intensity when used outdoors can be obtained according to the magnitude of the photocurrent detected by the detection circuit 140 of the embodiments of the present disclosure, the display brightness of the display layer 01 may be adjusted according to the magnitude of the photocurrent detected by the detection circuit 140.

The solar cell 02 provided by the embodiments of the present disclosure is equivalently to the ambient light sensor in the related art; for how to adjust the display brightness of the display layer 01 according to the magnitude of the photocurrent detected by the detection circuit 140, it is not to be limited and may be the same as the related art. It should be illustrated that when the processor 150 is adjusting the display brightness of the display layer 01, the overall brightness of the display layer 01 is adjusted. Taking mobile phones as the display device as an example, as shown in FIG. 9, the overall brightness of the display layer 01 may be adjusted by an adjustment button for adjusting the brightness.

Since the open-circuit voltage of ultraviolet light Voc is proportional to the irradiance in a wide dynamic range of 5 orders of magnitude, it reaches saturation at high irradiance, the short-circuit current of the ultraviolet light Isc is also proportional to the irradiance in the wide range, there is an accurate proportional relation between the irradiance and the output signal. On this basis, the display device provided by the embodiments of the present disclosure may further serve as a kind of ultraviolet radiation detector, the irradiance of the ultraviolet light may be obtained according to the magnitude of the photocurrent detected by the detection circuit 140.

Since the display device provided by the embodiments of the present disclosure may further effectively detect the irradiance of the invisible light such as ultraviolet light, while the ultraviolet light will cause damage to the human body, irradiance of outdoor ultraviolet light may be provided to the users according to the detected irradiance, to warn of unhealthy conditions when the value of the irradiance of ultraviolet light is high.

In some embodiments, the first electrode 10 or the second electrode 10 of the solar cell 02 is an electric energy output electrode, the electric energy output electrode is electrically connected with the power supply circuit of the display device or with a storage battery.

The storage battery may be the storage battery of the display device, or the storage battery used for storing electric energy converted by solar cell 02.

Herein, if the electric energy output electrode is electrically connected with the power supply circuit of the display device, the electric energy converted by the solar cell 02 is supplied to the display layer 01 directly; if the electric energy output electrode is connected with the storage battery, the electric energy converted by the solar cell 02 may first be stored in the storage battery, and then supplied to the display layer 01.

The embodiments of the present disclosure, since the electric energy output electrode of the solar cell 02 is electrically connected with the power supply circuit of the display device or with the storage battery, the electric energy converted by the invisible light such as ultraviolet light absorbed by the solar cell 02 may provided to the display layer 01 of the display device, standby duration of the display device is extended, the electric quantity of the storage battery of the display device is saved, and the problem that the display device cannot be continuously powered due to the limited electric quantity of the storage battery the display device while the display device cannot be operated normally is solved.

The above description, is only the specific embodiments of the present disclosure, but the protection scope of the present disclosure is not limited thereto, and any person skilled in the art can easily think of variations or replacements within the technical scope disclosed by the present disclosure, which are intended to be covered by the protection scope of the present disclosure. Therefore, the scope of protection of the present disclosure should be determined by the scope of the claims.

What is claimed is:

1. A display panel, wherein, the display panel comprises a display layer, and a solar cell disposed on the side of light emitting of the display layer and located on at least a part of display region of the display layer; the solar cell is used to supply power for the display layer;
the solar cell comprises a first electrode and a second electrode which are transparent, and a photoelectric conversion layer disposed between the first electrode and the second electrode, the photoelectric conversion layer is configured to transmit at least a part of visible light, and to convert the absorbed light into electrical energy.

2. The display panel according to claim 1, wherein, the photoelectric conversion layer is configured to transmit visible light, and to absorb invisible light and to convert the absorbed invisible light into electrical energy.

3. The display panel according to claim 2, wherein, the invisible light is ultraviolet light.

4. The display panel according to claim 1, wherein, the photoelectric conversion layer comprises a first semiconductor layer and a second semiconductor layer;
the first semiconductor layer contacts the second semiconductor layer for forming a heterojunction.

5. The display panel according to claim 4, wherein, the first semiconductor layer and the second semiconductor layer are stacked.

6. The display panel according to claim 5, wherein, the material of the first semiconductor layer is N-type semiconductor material, the material of the second semiconductor layer is P-type semiconductor material; the work function of the first electrode is lower than the work function of the second electrode;
wherein, the first semiconductor layer is closer to the first electrode than the second semiconductor layer.

7. The display panel according to claim 4, wherein, the material of the first semiconductor layer is selected from at least one of niobium-doped strontium titanate or niobium-doped titanium oxide.

8. The display panel according to claim 7, wherein, the concentration of the niobium-doped strontium titanate or niobium-doped titanium oxide is 0.007˜0.013 wt %, in terms of element niobium.

9. The display panel according to claim 4, wherein, the material of the second semiconductor is selected from at least one of Poly(3,4-ethylenedioxythiophene):poly(styrenesulfonate), Poly[2-methoxy-5-(2-ethylhexyloxy)-1,4-phenylenevinylene], or Poly[(5-(2-ethylhexyl)-5,6-dihydro-4,6-dioxo-4H-thieno[3,4-c]pyrrole-1,3-diyl](4,4′-didodecyl [2,2′-bithiophene-5,5′-diyl)].

10. The display panel according to claim 4, wherein, the thickness of the first semiconductor layer is 0.5 μm˜1 mm.

11. The display panel according to claim 10, wherein, the thickness of the first semiconductor layer is 50 μm˜500 μm.

12. The display panel according to claim 4, wherein, the thickness of the second semiconductor layer is 0.1 μm˜5 μm.

13. The display panel according to claim 12, wherein, the thickness of the second semiconductor layer is 0.3 μm˜1 μm.

14. The display panel according to claim 4, wherein, the first electrode, the first semiconductor layer, the second semiconductor layer and the second electrode are sequentially disposed along the light emitting direction of the display layer.

15. The display panel according to claim 4, wherein, the second electrode, the second semiconductor layer, the first semiconductor layer and the first electrode are sequentially disposed along the light emitting direction of the display layer.

16. The display panel according to claim 1, wherein, the solar cell is disposed such that in a case where the display layer comprises a plurality of top-emitting light display units, the solar cell is disposed on the top of the display layer; or,
in a case where the display layer comprises a plurality of bottom-emitting light display units, the solar cell is disposed on the bottom of the display layer.

17. A display device, wherein, the display device comprises the display panel according to claim 1.

18. The display device according to claim 17, wherein, the photoelectric conversion layer is configured to transmit visible light, to absorb invisible light and to convert the absorbed invisible light into electrical energy,
the display device further comprises a detection circuit and a processor;
the detection circuit is connected with the first electrode and the second electrode respectively, for detecting the magnitude of the photocurrent output from the first electrode and the second electrode;
the processor is connected with the detection circuit, for adjusting the display brightness of the display layer according to the magnitude of the photocurrent detected by the detection circuit; and/or for obtaining the irradiance of the invisible light according to the magnitude of the photocurrent detected by the detection circuit, and outputting the value of the irradiance of the invisible light.

19. The display device according to claim 17, wherein, the first electrode and the second electrode of the solar cell are electric energy outputting electrodes which are connected with the power supply circuit of the display device or with a storage battery.

20. The display device according to claim 18, wherein, the invisible light is ultraviolet light.
